(19) United States
(12) Patent Application Publication
(10) Pub. No.: US 2019/0101123 A1
(43) Pub. Date: Apr. 4, 2019

(54) COOLING DEVICE

(71) Applicant: AISIN SEIKI KABUSHIKI KAISHA, Kariya-shi (JP)

(72) Inventors: Naoki MATSUMURA, Nagoya-shi (JP); Hiroto OMORI, Kariya-shi (JP); Eigo KIYOHARA, Chiryu-shi (JP)

(73) Assignee: AISIN SEIKI KABUSHIKI KAISHA, Kariya-shi (JP)

(21) Appl. No.: 16/149,529

(22) Filed: Oct. 2, 2018

(30) Foreign Application Priority Data
Oct. 3, 2017 (JP) 2017-193717

(51) Int. Cl. F04D 19/00; F28F 3/02; H05K 7/20; H01L 23/467; H01L 23/40

(52) U.S. Cl. CPC F04D 19/002; F28F 3/022; H05K 7/20863; H05K 7/20854; H01L 23/467; H01L 2023/4043; H05K 7/20172; H05K 7/20154; F28F 2250/08; H01L 2023/4087; H01L 23/4006

(57) ABSTRACT

A cooling device includes: a fan motor including a rotation shaft, an impeller supported by the rotation shaft, and a sleeve bearing unit pivotally supporting the rotation shaft; and a heat sink including heat radiation pins extending from a base portion. The fan motor is placed on the heat sink. The impeller includes a blade support element supported by the rotation shaft and a fan blade extending from the blade support element in an outer peripheral direction of the rotation shaft. The heat radiation pins extend from the base portion toward the sleeve bearing unit in a direction along the rotation shaft. The impeller is spaced apart from the heat radiation pins between the sleeve bearing unit and the heat radiation pins. The blade support element and at least one of the heat radiation pins overlap with each other as viewed in a direction of the rotation shaft.

### CROSS REFERENCE TO RELATED APPLICATIONS

This application is based on and claims priority under 35 U.S.C. § 119 to Japanese Patent Application 2017-193717, filed on Oct. 3, 2017, the entire contents of which are incorporated herein by reference.

### TECHNICAL FIELD

This disclosure relates to a cooling device which includes a fan motor including a rotation shaft, an impeller supported by the rotation shaft so as to rotate integrally with the rotation shaft, and a sleeve bearing unit configured to pivotally support the rotation shaft, and a heat sink including a plurality of heat radiation pins extending from a base portion.

### BACKGROUND DISCUSSION

JP 2012-216645A (Reference 1) discloses a fan (so-called a fan motor) which includes a fan case, a rotator including an impeller and a shaft (so-called a rotation shaft) and accommodated in the fan case so as to rotate around the shaft thereof, a bearing unit provided in the fan case and supporting the shaft, and a motor unit. The fan is provided with a movement restriction structure that restricts movement of the rotator in a direction of being separated from the bearing unit.

The movement restriction structure of the fan includes a contact element provided in the rotator and a restriction element provided in the fan case. The restriction element is configured to be able to come into contact with and be separated from the contact element. For example, a fluid bearing (an example of a sleeve bearing) is employed in the bearing unit of the fan, and the rotator including the shaft is separable from the bearing unit. Thus, when the rotator moves in a direction of being separated from the bearing unit, the restriction element comes into contact with the contact element, thereby preventing a separation of the rotator.

The fan described in Reference 1 is equipped with the provision of the movement restriction structure, and as a result, immediately returns to the original state even if an impact is applied to the fan and a force is applied to the rotator of the fan to move the rotator in a direction of being separated from the bearing unit so that the contact element and the restriction element come into contact with each other. Thus, it is possible to avoid a poor rotation of the rotator. Thus, it is possible to avoid a reduction in blowing efficiency.

JP 2001-110956A (Reference 2) discloses a cooling appliance (a cooling device) for electronic components which includes a base configured to be brought into contact with a heating element to be cooled, a heat radiation unit (so-called heat sink) formed of pins bonded to the base, and a cooling fan disposed immediately above the heat radiation unit.

The configuration of the fan described in Reference 1 has a problem in that the number of components increases, which causes a complicated structure since it is necessary to add the restriction element as a separate component from the fan.

In addition, as in the configuration of the cooling appliance described in Reference 2, in a case where the fan described in Reference 1 is attached to the heat sink to be used as an integrated cooling device, the restriction element inhibits the air stream of the fan, and there is a risk of deteriorating the cooling performance of the heat sink.

Therefore, it is required to provide a cooling device having a simplified structure.

Thus, a need exists for a cooling device which is not susceptible to the drawback mentioned above.

### SUMMARY

A feature of a cooling device according to an aspect of this disclosure resides in that the cooling device includes a fan motor including a rotation shaft, an impeller supported by the rotation shaft to rotate integrally with the rotation shaft, and a sleeve bearing unit configured to pivotally support the rotation shaft. The cooling device also includes a heat sink including a plurality of heat radiation pins extending from a base portion. The fan motor is placed on the heat sink, and the impeller includes a blade support element supported by the rotation shaft and a fan blade extending from the blade support element in an outer peripheral direction of the rotation shaft. The heat radiation pins extend from the base portion toward the sleeve bearing unit in a direction along the rotation shaft. The impeller is spaced apart from the heat radiation pins between the sleeve bearing unit and the heat radiation pins, and the blade support element and at least one of the heat radiation pins overlap with each other as viewed in an axial direction of the rotation shaft.

### BRIEF DESCRIPTION OF THE DRAWINGS

The foregoing and additional features and characteristics of this disclosure will become more apparent from the following detailed description considered with the reference to the accompanying drawings, wherein:

FIG. 1 is a schematic view illustrating a configuration of a cooling device;

FIG. 2 is a perspective view of a fan motor as viewed from the side of a heat sink; and

FIG. 3 is an explanatory view of an attachment mode of a fan motor to the heat sink.

### DETAILED DESCRIPTION

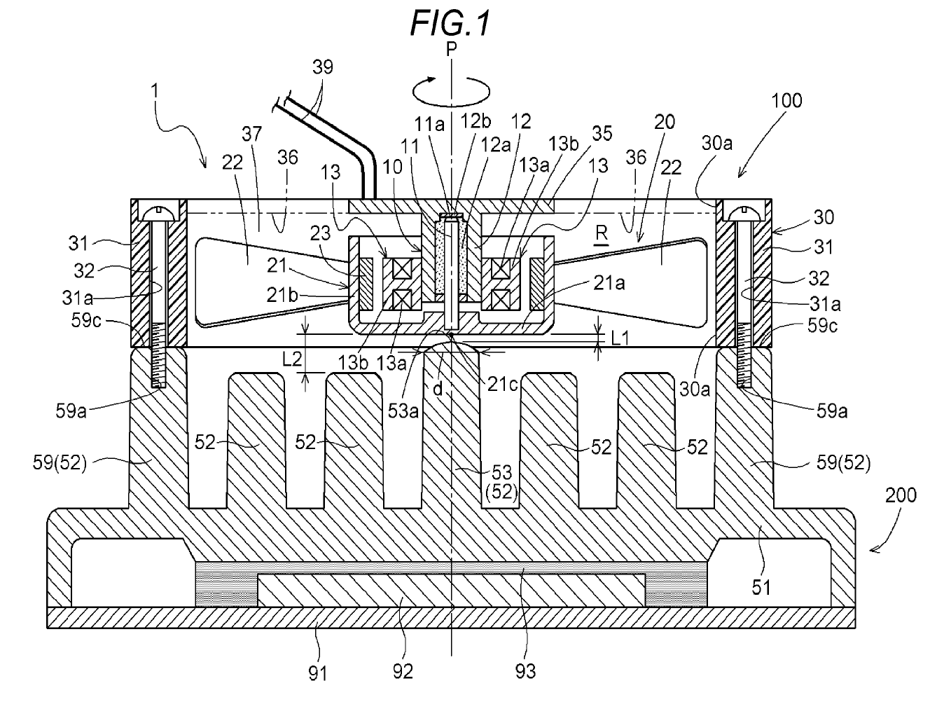

A cooling device 1 according to an embodiment disclosed here will be described with reference to FIGS. 1 to 3.

As illustrated in FIG. 1, the cooling device 1 according to the present embodiment is used for cooling a heating element 92 such as, for example, an integrated circuit (so-called IC). The heating element 92 may be used, for example, in an in-vehicle apparatus that is equipped in a vehicle. Any irregular and indefinite vibration or impact may be applied to the in-vehicle apparatus as the vehicle travels.

### <Description of Schematic Configuration of Cooling Device>

FIG. 1 is a schematic cross-sectional view for explaining a schematic configuration of the cooling device 1.

As illustrated in FIG. 1, the cooling device 1 according to the present embodiment includes a fan motor 100 which includes a rotation shaft 11, an impeller 20 supported by the rotation shaft 11 so as to rotate integrally with the rotation shaft 11, and a bearing unit 10 (an exemplary sleeve bearing unit) pivotally supporting the rotation shaft 11, and a heat sink 200 which includes a plurality of heat radiation pins 52 extending from a base portion 51.

The fan motor 100 is placed on the heat sink 200.

In the present embodiment, a case where the cooling device 1 is a fan-attached heat sink that cools the heat sink using air blowing by a fan is described by way of example.

The impeller 20 of the fan motor 100 includes a blade support element 21 supported by the rotation shaft 11 and a fan blade 22 extending from the blade support element 21 in the outer peripheral direction of the rotation shaft 11.

The heat radiation pins 52 of the heat sink 200 extend from the base portion 51 toward the bearing unit 10 in a direction along the rotation shaft 11.

Then, the impeller 20 is provided between the bearing unit 10 and the heat radiation pins so as to be spaced apart from the heat radiation pins 52.

Then, the blade support element 21 and at least one heat radiation pin 52 overlap each other as viewed in the axial direction of the rotation shaft 11.

In addition, the fan blade 22 is provided at a position at which it is farther away from the heat radiation pins 52 than the blade support element 21.

As described above, in the cooling device 1, since the heat radiation pins 52 extend from the base portion 51 of the heat sink 200 toward the bearing unit 10 of the fan motor 100 in a direction along a rotational axis P of the rotation shaft 11 of the fan motor 100 (the axial direction of the rotational axis P), a top portion of the heat radiation pins 52 is provided so as to be spaced apart from the impeller 20 in a state of being opposed to the impeller 20 of the fan motor 100.

When viewing the cooling device 1 from the bearing unit 10 side in the axial direction of the rotational axis P, the bearing unit 10, the rotation shaft 11, the impeller 20, the heat radiation pins 52, and the base portion 51 are respectively arranged in the order of the bearing unit 10, the rotation shaft 11, the impeller 20, the heat radiation pins 52, and the base portion 51.

In the present embodiment, moreover, as a portion of the plurality of heat radiation pins 52, there is provided a support pin 53 which is longer than the other heat radiation pins 52, and the blade support element 21 and the support pin 53 overlap with each other as viewed in the axial direction of the rotational axis P of the rotation shaft 11.

Hereinafter, the configuration of the cooling device 1 will be described in detail.

### <Description of Detailed Configuration of Cooling Device>

<Description related to Fan Motor>

First, the fan motor 100 will be described with reference to FIGS. 1 to 3.

As illustrated in FIG. 1, the fan motor 100 includes the rotation shaft 11, the bearing unit 10, the impeller 20, and a frame 30 which accommodates the rotation shaft 11, the bearing unit 10, and the impeller 20.

The fan motor 100 is a so-called axial flow fan. The fan motor 100 may blow air in the axial direction of the rotational axis P. In the present embodiment, a case where the fan motor 100 blows the air in a direction from the fan motor 100 toward the heat sink 200 along the axial direction of the rotational axis P is described.

In addition, in the following description, the axial direction of the rotational axis P may be simply referred to as “axial direction”.

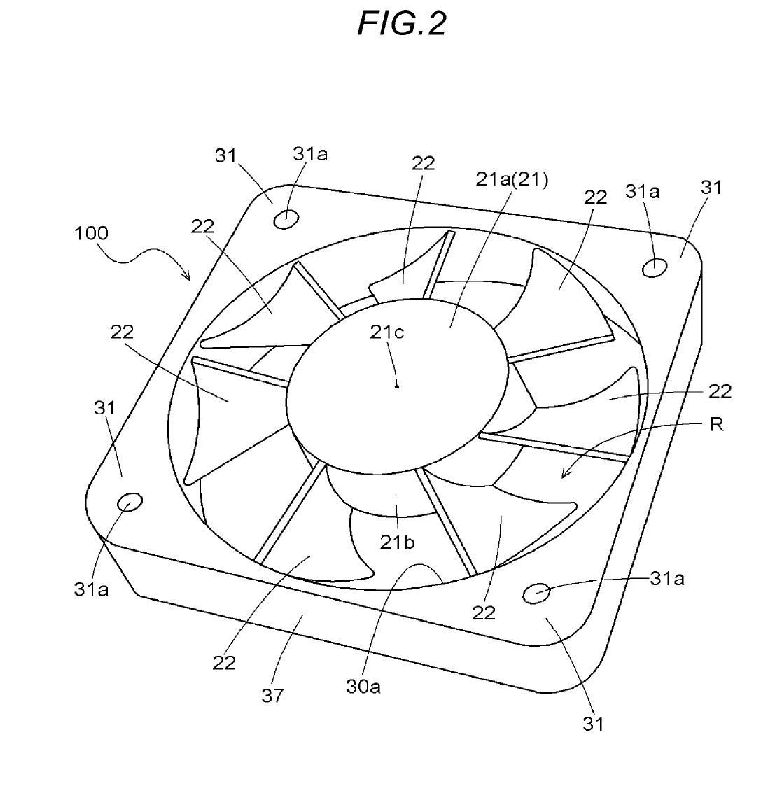

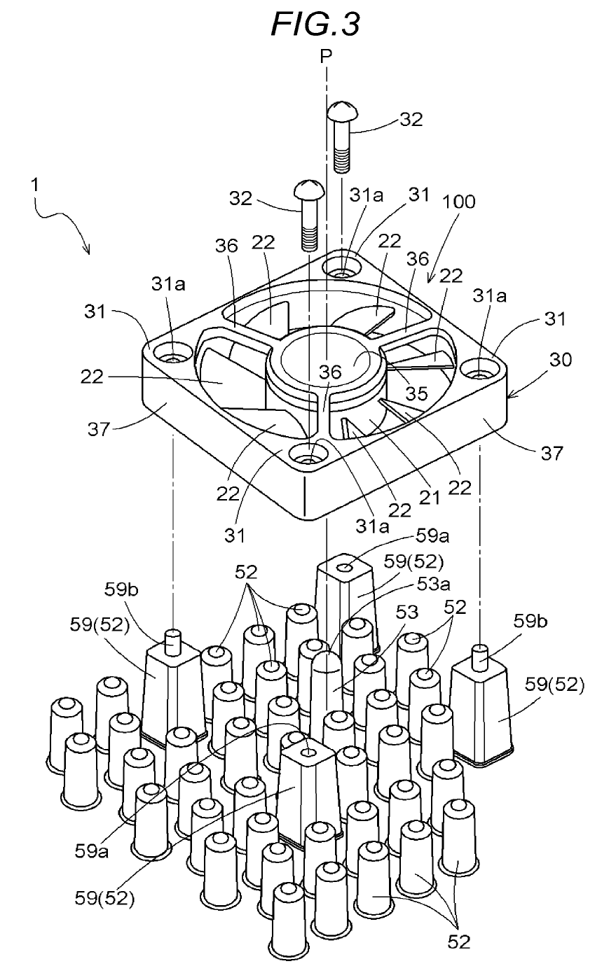

The frame 30 is a casing that accommodates the bearing unit 10 and the impeller 20. The frame 30 mainly includes a wall portion 37 which surrounds the bearing unit 10 and the impeller 20 at the outer peripheral side, an attachment plate portion 35 to which the bearing unit 10 is attached, a support column 36 by which the attachment plate portion 35 is supported on the wall portion 37, and an attachment portion 31 which fixes the frame 30 to the heat sink 200. In the present embodiment, as illustrated in FIGS. 2 and 3, the frame 30 is a rectangular (square) wall body in which four wall portions 37 are integrated and four corners as viewed in the axial direction are R-chamfered.

An accommodating space R is formed inside the wall portion 37 to accommodate the bearing unit 10 and the impeller 20. That is, the bearing unit 10 and the impeller 20 are arranged in the accommodating space R surrounded by the wall portion 37. Both sides in the axial direction of the accommodating space R (one side and the other side in the axial direction of the frame 30) are open as an opening portion 30a toward an external space. As the impeller 20 rotates, air circulates inside the accommodating space R so that wind is sent (blown) toward the heat sink 200.

The present embodiment exemplifies a case where the frame 30 including the wall portion 37, the attachment plate portion 35, the support column 36, and the attachment portion 31 is integrally formed by an injection molding of a plastic material. In addition, the frame 30 is not limited to a plastic material. For example, instead of the plastic material, a metal material such as, for example, an aluminum alloy may be used. In addition, the method of forming the frame 30 is not limited to injection molding. For example, the frame may be formed by a cutting method.

As illustrated in FIGS. 1 and 3, the attachment portion 31 serves to fix the frame 30 (the fan motor 100) to the heat sink 200.

The attachment portion 31 is provided at four corners of the frame 30 (connecting portions between respective adjacent wall portions 37).

As illustrated in FIG. 1, each attachment portion 31 has an attachment hole 31a. The attachment hole 31a is oriented along the axial direction and takes the form of a through-hole.

The attachment hole 31a is a hole following an axial direction to be formed as a through hole. The attachment hole 31a is formed by spot facing and has a shoulder portion by which a head portion of a screw 32 pushes the frame 30 toward the heat sink 200.

The frame 30 is fixed to the heat sink 200 by screwing a screw portion of the screw 32 inserted through the attachment hole 31a into a screw hole 59a in the heat sink 200 to be described later. That is, the fan motor 100 is fixed to the heat sink 200 using the screw 32.

As illustrated in FIG. 1, the attachment plate portion 35 is a plate-shaped fixed seat that fixes the bearing unit 10 to the frame 30. The plate surface of the attachment plate portion 35 is provided so as to orthogonally intersect with the rotational axis P. The bearing unit 10 is provided on the surface of the attachment plate portion 35 that faces the heat sink 200.

As illustrated in FIGS. 1 and 3, the attachment plate portion 35 is supported on the frame 30 using a plurality of (three in the present embodiment) support columns 36. In addition, the attachment plate portion 35 is provided so as to be spaced apart from the wall portion 37. Then, the attachment plate portion 35 is provided so as to overlap with a portion of the opening portion 30a in the frame 30 in the axial direction.

In the present embodiment, as illustrated in FIG. 1, the attachment plate portion 35 is supported by the support columns 36 which extend from the wall portion 37 in a direction orthogonal to the axial direction. The support columns 36 extend so as to overlap with the opening portion 30a of the side other than the side that is opposed to the heat sink 200 in the axial direction. That is, the attachment plate portion 35 is provided on an end portion of the fan motor 100 at the side other than the side that is opposed to the heat sink 200 in the axial direction.

As illustrated in FIG. 1, the bearing unit 10 is a sleeve type bearing that pivotally supports the rotation shaft 11.

In the present embodiment, a fluid bearing structure (fluid bearing), which is one mode of a sleeve type bearing structure (hereinafter simply referred to as a sleeve bearing) is described by way of example.

The bearing unit 10 includes a cylindrical element 12 in the form of a bottomed cylinder as a body portion thereof, a thrust bearing 12b provided on the bottom of the cylindrical element 12, and a radial bearing 12a (an exemplary fluid bearing) provided inside the cylinder of the cylindrical element 12.

In the present embodiment, a stator 13, which configures a plurality of electromagnets including a magnetic body 13b and a coil 13a formed by winding an electric wire around the magnetic body 13b, is provided on the outer peripheral portion of the cylindrical element 12 so that a magnetic pole thereof faces the outer peripheral direction. Power (e.g., direct current) is supplied to the stator 13 via two power lines 39.

A cylinder portion of the cylindrical element 12 is oriented along the axial direction. The cylinder portion of the cylindrical element 12 has a cylindrical shape. In addition, an opening portion of the bottomed cylinder of the cylindrical element 12 is provided on the attachment plate portion 35 so as to face the heat sink 200.

Both the thrust bearing 12b and the radial bearing 12a are formed of a metal sintered body, for example, and are impregnated with oil.

Grooves (not illustrated) are formed in the rotation shaft 11, and at portions facing each other between the thrust bearing 12b and the radial bearing 12a so as to circulate oil to flow through at least one of the thrust bearing 12b and the radial bearing 12a to generate a pressure. When the rotation shaft 11 rotates in a state where the rotation shaft 11 is inserted into the bottomed cylinder of the cylindrical element 12, a dynamic pressure is generated in the oil so that the rotation shaft 11 rotates without being in contact with the sintered body of the thrust bearing 12b and the radial bearing 12a.

As illustrated in FIG. 1, the impeller 20 is a blowing mechanism in the fan motor 100. The impeller 20 rotates integrally with the rotation shaft 11.

The impeller 20 includes the blade support element 21 which is fixed to and supported by the rotation shaft 11, the fan blade 22 which is a blade mechanism (propeller) that blows air, and a magnet 23 which forms an electric motor mechanism together with the stator 13 of the bearing unit 10.

In the present embodiment, the blade support element 21 and the fan blade 22 of the impeller 20 are integrally formed by an injection molding of a plastic material.

The blade support element 21 is formed into a bottomed cylinder shape. The blade support element 21 includes a base 21a which is a bottom portion of the bottomed cylinder shape and a body 21b which is a cylindrical body portion.

The blade support element 21 is provided such that a cylindrical portion of the bottomed cylinder is oriented along the axial direction. The blade support element 21 is provided such that an opening portion of the bottomed cylinder faces the side opposite to the heat sink 200 in the axial direction.

The base 21a is fixed to the rotation shaft 11 at a portion thereof corresponding to the rotational axis (coinciding with the rotational axis P) of the impeller 20. The base 21a is connected so as to rotate integrally with the rotation shaft 11 at the side opposite to the heat sink 200 in the axial direction (i.e., the surface inside the bottomed cylinder of the blade support element 21).

A rotation center portion (i.e., a portion 21c through which the rotational axis P passes in FIG. 1) of the surface of the base 21a that faces the heat sink 200 is opposed close to a top portion of the support pin 53 of the heat sink 200 to be described later in detail.

The fan blade 22 is provided on the outer peripheral portion of the body 21b.

The fan blade 22 is provided on the body 21b so as to extend outwardly from the body 21b in the outer peripheral direction (a direction orthogonal to the rotational axis P). The fan blade 22 has a curved plate shape, i.e. a so-called propeller shape.

In the present embodiment, as illustrated in FIGS. 2 and 3, the fan blade 22 is provided so as to be rotatable integrally with the body 21b in a mode such that an edge of the fan blade 22 located at the side opposite to the side that faces the heat sink 200 in the axial direction moves forward in a predetermined rotational direction (in the present embodiment, in a clockwise direction as viewed in the plane of FIG. 3). Thus, when the impeller 20 rotates in the predetermined rotational direction, the fan motor 100 may blow air toward the heat sink 200.

As illustrated in FIG. 1, the magnet 23 is provided on the inner peripheral portion of the body 21b. The magnet 23 is attached to the body 21b such that a magnetic pole thereof faces the radial direction.

The magnet 23 is provided on the body 21b at a position at which the magnet 23 is opposed to the stator 13 of the bearing unit 10 in the radial direction when the impeller 20 is attached to the bearing unit 10, that is, when the rotation shaft 11 is inserted into the bearing unit 10.

The blade support element 21 to which the magnet 23 is attached and the stator 13 form an integrated electric motor mechanism in a state where the impeller 20 is attached to the bearing unit 10. That is, the blade support element 21 is a rotor. The present embodiment exemplifies a case where the magnet 23 and the stator 13 form a DC type electric motor.

<Description related to Heat Sink>

As illustrated in FIG. 1, the heat sink 200 is a cooling device that receives thermal energy supplied from a heating element 92 and dissipates the thermal energy to air (heat exchange with the air). The heat sink 200 is thermally connected to, for example, an integrated circuit as the heating element 92 mounted on a printed circuit board 91.

The heat sink 200 includes the base portion 51 which is thermally connected to the heating element 92 and the plurality of heat radiation pins 52 which dissipate thermal energy supplied by heat conduction from the base portion 51 to the air.

In the heat sink 200 of the present embodiment, the base portion 51 and the heat radiation pins 52 are integrally formed by an injection molding of an aluminum alloy (so-called aluminum die casting). In addition, a material forming the heat sink 200 is not limited to an aluminum alloy. For example, the heat sink may be formed of any other metal or metal alloy having thermal conductivity. In addition, the method of forming the heat sink 200 is not limited to injection molding. For example, the heat sink may be formed by a cutting method.

In the present embodiment, the base portion 51 is placed on the printed circuit board 91 on which the heating element 92 is mounted. The base portion 51 is thermally connected to the heating element 92 via a heat conductive sheet 93. That is, by the heat conduction, the thermal energy of the heating element 92 is transferred from the heating element 92 to the heat conductive sheet 93, and is further transferred from the heat conductive sheet 93 to the base portion 51.

The base portion 51 is formed to have a body portion having a slightly thick plate shape. The plate-shaped body portion of the base portion 51 is placed on the printed circuit board 91. In the present embodiment, a leg portion of the base portion 51, an end portion of which is curved toward the printed circuit board, is placed on the printed circuit board 91 so as to be in contact with the printed circuit board 91.

The heat conductive sheet 93 is provided between the base portion 51 and the heating element 92 so that a gap between the base portion 51 and the heating element 92 is filled with the heat conductive sheet 93.

The base portion 51 is fixed to the printed circuit board 91 so as to press the heating element 92 with a predetermined pressure in a state where the heat conductive sheet 93 is provided thereto.

The base portion 51 may be fixed to the printed circuit board 91 using, for example, a screw or a spring clip. In the present embodiment, the base portion 51 is screwed (not illustrated) to the printed circuit board 91.

The heat radiation pins 52 are formed into a columnar shape, and each heat radiation pin 52 extends vertically upward from the base portion 51, i.e., toward the fan motor 100 in a direction parallel to the rotational axis P. That is, the heat radiation pin 52 is a column that extends from the base portion 51 toward the impeller 20.

As illustrated in FIGS. 1 and 3, the plurality of heat radiation pins 52 include the support pin 53 and a mounting portion 59 to be described later.

The heat radiation pins 52 other than the support pin 53 and the mounting portion 59 are arranged on the base portion 51 in multiple lines of triangular hound's tooth checks in a planar view (as viewed in the axial direction). In addition, the arrangement of the heat radiation pins 52 is not limited to the triangular hound's tooth checks, but may be any other regular arrangement (hereinafter referred to as a predetermined regular arrangement) such as a tetragonal lattice pattern, for example.

In the present embodiment, as illustrated in FIG. 3, a case has been described where the heat radiation pins 52 excluding the mounting portion 59 have a cylindrical shape that is slightly reduced in diameter upwardly from the base portion 51.

In the present embodiment, a case has been described where the mounting portion 59 takes the form of a quadrangular pyramid that is slightly reduced in diameter upwardly from the base portion 51 and four corners of the quadrangular pyramid are R-chamfered by way of example.

As illustrated in FIGS. 1 and 3, the support pin 53 is provided as one of the plurality of heat radiation pins 52. In the present embodiment, one support pin 53 is provided.

The length of the support pin 53 from the base portion 51 to the tip end (hereinafter simply referred to as the length of the support pin 53) is relatively longer than the length of the other heat radiation pins 52 including the mounting portion 59 from the base portion 51 to the tip end (hereinafter referred to simply as the length of the heat radiation pins 52).

In the present embodiment, by setting the length of the support pin 53 to be longer than the length of the other heat radiation pins 52, the heat exchange capability (i.e., the heat radiation capability) of all of the heat radiation pins 52 (the heat sink 200) is enhanced.

The top portion of the column of the support pin 53, i.e., the tip end portion, is a curved portion 53a that forms an upwardly convex smooth curved surface. In the present embodiment, the curved portion 53a is formed as an SR spherical surface. In addition, the SR spherical surface is a curved surface that forms a portion of a spherical surface of a virtual sphere having a predetermined diameter. The curved portion 53a may be an SR spherical surface having a diameter equal to or larger than the diameter of a circle including the cross section of the support pin 53. That is, since the support pin 53 is a cylinder in the present embodiment, the curved portion 53a may be an SR spherical surface having a diameter equal to or larger than the diameter d of the support pin 53. In the present embodiment, FIG. 1 illustrates a case where the curved portion 53a is an SR spherical surface having a diameter 1.2 times the diameter d of the portion of the support pin 53 having the smallest diameter.

The support pin 53 is disposed such that the axis of the support pin 53, i.e., the axis passing through a center of gravity of the cross section of the support pin 53, and the rotational axis P are coaxial.

As one of the plurality of heat radiation pins 52, the frame 30, i.e., the mounting portion 59 on which the frame 30 is placed, is provided. In the present embodiment, four mounting portions 59 are provided. The mounting portion 59 is provided on a tip end portion thereof with a seat surface portion 59c on which the attachment portion 31 is placed. The seat surface portion 59c is provided as a surface portion that orthogonally intersects with the axial direction.

In the present embodiment, by forming the mounting portion 59 as one of the plurality of heat radiation pins 52, the heat exchange capability (i.e., the heat radiation capability) of all of the heat radiation pins 52 (the heat sink 200) is enhanced, as compared with a case of providing the mounting portion 59 that does not function as the heat radiation pin 52.

As illustrated in FIG. 1, the mounting portion 59 is formed so that the length of the mounting portion 59 from the base portion 51 to the seat surface portion 59c (hereinafter simply referred to as the length of the mounting portion 59) is equal to or larger than the length of the heat radiation pins 52 (i.e., the length of the heat radiation pin 52 or longer) and is shorter than the length of the support pin 53 (i.e., less than the length of the support pin 53).

As illustrated in FIG. 3, in the present embodiment, four mounting portions 59 are provided so as to correspond to the arrangement of the attachment portions 31 provided at the four corners of the frame 30. FIG. 3 illustrates a mode in which screw holes 59a are formed in a pair of mounting portions 59 on a diagonal line so that the fan motor 100 may be fixed by the screws 32. In addition, FIG. 3 illustrates a case where protrusions 59b are formed at the tip ends of a pair of mounting portions 59 separate from the pair of mounting portions 59 having the screw holes 59a, so that the protrusions 59b are fitted into the attachment holes 31a for positioning the frame 30.

<Description related to Relationship between Fan Motor and Each Component of Heat Sink>

Relationships between the heat radiation pin 52, the support pin 53, and the blade support element 21 will be described in detail.

In the present embodiment, as illustrated in FIG. 1, the support pin 53 of the heat sink 200 and the blade support element 21 of the fan motor 100 are formed so as to be spaced apart from each other only by a distance L1. In addition, the other heat radiation pins 52 (excluding the mounting portions 59) and the blade support element 21 are formed so as to be spaced apart from each other only by a distance L2 which is longer than the distance L1.

The present embodiment exemplifies a case where the distance L1 is set to 1 mm. The distance L1 may be 20% or less of the length of the rotation shaft 11 and may also be 0.5 mm or more.

When the distance L1 is excessively shorter than 0.5 mm, the support pin 53 and the base 21a of the blade support element 21 may be brought into contact with each other even when no impact is applied thereto, thereby being excessively come into contact with each other.

When the distance L1 exceeds 20% of the length of the rotation shaft 11, the rotational speed of the impeller 20 may be easily reduced when the blade support element 21 and the top portion of the curved portion 53a of the support pin 53 come into contact with each other due to an impact.

In the present embodiment, a portion of the support pin 53 is disposed in a state of being introduced into the accommodating space R and the other heat radiation pins 52 are disposed outside the accommodating space R. In addition, in the present embodiment, a case where a portion of the curved portion 53a as a portion of the support pin 53 is introduced into and exists in the accommodating space R is illustrated in FIG. 1.

As described above, by introducing only a portion of the support pin 53 into the accommodating space R and disposing the other heat radiation pins 52 only outside the accommodating space R, it is possible to reliably prevent separation of the impeller 20 and to prevent the fan blade 22 from colliding with the heat radiation pins 52 even when the blade support element 21 and the top portion of the curved portion 53a of the support pin 53 come into contact with each other.

Relationships between the bearing unit 10, the impeller 20, and the support pin 53 will be described.

The blade support element 21 of the impeller 20 generates an attractive force with the stator 13 of the bearing unit 10 therebetween by a magnetic force of the magnet 23. Thus, the impeller 20 and the rotation shaft 11 supporting the impeller 20 usually maintain a predetermined positional relationship with respect to the bearing unit 10. However, when an impact is applied to the cooling device 1, the impeller 20 may be subjected to a force that moves the impeller 20 in a direction of being separated from the bearing unit 10. In this case, when the movement force becomes larger than the attractive force generated between the magnet 23 and the stator 13, the impeller 20 may move in the direction of being separated from the bearing unit 10.

When the impeller 20 moves in the direction of being separated from the bearing unit 10 (i.e., to the side facing the heat sink 200 in the axial direction) together with the rotation shaft 11 along the axial direction of the rotation shaft 11, the support pin 53 first comes into direct contact (collides) with the blade support element 21 (the base 21a) prior to the heat radiation pins 52.

The distance L1 between the support pin 53 and the blade support element 21 is shorter than the length by which the rotation shaft 11 is inserted into the radial bearing 12a. Thus, it is possible to prevent (avoid) the impeller 20 from being separated from the bearing unit 10.

The impeller 20 which has moved in the direction of being separated from the bearing unit 10 moves in a direction opposite to the direction of being separated from the bearing unit 10 (i.e., moves in a direction of returning to the original position) by the attractive force generated between the magnet 23 and the stator 13 after coming into contact with the support pin 53 (after avoiding separation). As a result, the bearing unit 10 and the impeller 20 recover a predetermined positional relationship.

The contact of the support pin 53 is supplementally described.

As described above, when the support pin 53 disposed coaxially with the rotational axis P comes into contact with the blade support element 21, the support pin 53 comes into contact with the portion 21c of the blade support element 21 that overlaps with the rotational axis P, i.e., the portion of the impeller 20 having the smallest movement speed.

Thus, a frictional resistance between the support pin 53 and the blade support element 21 is minimized.

Moreover, since the tip end portion of the support pin 53, i.e., the curved portion 53a is, for example, a curved surface having a smooth SR shape, the frictional resistance between the support pin 53 and the blade support element 21 is further reduced.

The wear of the support pin 53 or the blade support element 21 is suppressed by reducing the frictional resistance between the support pin 53 and the blade support element 21. In addition, a reduction in the rotation speed of the impeller 20 is also suppressed. Thus, the robustness of a cooling function in the cooling device 1 is enhanced.

As described above, it is possible to provide a cooling device having a simplified structure using a fan motor which employs a sleeve bearing.

### Other Embodiments

(1) In the above embodiment, a case where the bearing unit 10 is a fluid bearing structure which is one mode of a sleeve bearing has been exemplified.

However, the bearing unit 10 is not limited to the fluid bearing structure, but may be any other so-called sleeve bearing.

(2) In the above embodiment, a case where the support pin 53 is used as one of the heat radiation pins 52 has been exemplified.

However, the support pin 53 may not be used. For example, a configuration in which, when the impeller 20 moves in a direction of being separated from the bearing unit 10 together with the rotation shaft 11 along the axial direction of the rotation shaft 11, the plurality of heat radiation pins 52 and the blade support element 21 may be brought into contact with each other so as to prevent separation of the impeller 20 may be possible.

(3) In the above embodiment, a case where the axis of the support pin 53 is disposed coaxially with the rotational axis P has been exemplified.

However, the axis of the support pin 53 may not be coaxial with the rotational axis P. Even in this case, as long as the blade support element 21 and the support pin 53 are disposed so as to overlap with each other as viewed in the axial direction of the rotational axis P of the rotation shaft 11, when the impeller 20 moves in the direction of being separated from the bearing unit 10 together with the rotation shaft 11 along the axial direction of the rotation shaft 11, the support pin 53 and the blade support element 21 may be brought into contact with each other so as to prevent a separation of the impeller 20.

For example, although the heat sink 200 may have a significantly simplified structure when the heat radiation pins 52 including the support pin 53 are arranged on the base portion 51 in a predetermined regular arrangement such as, for example, triangular hound's tooth checks, when giving priority to making the regular arrangement, the axis of the support pin 53 is not coaxial with the rotational axis P in some cases. Accordingly, the axis of the support pin 53 may not be coaxial with the rotational axis P when giving priority to simplify the structure of the heat sink 200.

(4) In the above embodiment, a case where the tip end portion of the column of the support pin 53 is the curved portion 53a that forms an upwardly convex smooth curved surface has been exemplified.

However, instead of forming the curved portion 53a at the tip end portion of column of the support pin 53, the tip end portion of the column of the support pin 53 may be formed into an upwardly convex conical shape. In this case, since the tip end of the column of the support pin 53 (the top portion of the cone) and the blade support element 21 are in point contact with each other, a frictional resistance may be reduced as in the case where the curved portion 53 a is formed at the tip end portion of the column of the support pin 53.

(5) In the above embodiment, a case where the heat radiation pins 52 are formed into a cylindrical shape has been exemplified.

However, the heat radiation pins 52 may have a pyramidal or triangular column shape. In addition, in order to secure a contact area with the air, the cross section of the heat radiation pin 52 may have a star shape (pleat shape).

(6) In the above embodiment, a case where the fan motor 100 blows air from the fan motor 100 toward the heat sink 200 has been exemplified.

However, a configuration in which the fan motor 100 discharges wind by attracting air from the heat sink 200 may be possible.

(7) In the above embodiment, a case where the base portion 51 of the heat sink 200 is placed on the printed circuit board 91 has been exemplified.

However, the heat sink 200 may be integrally formed with, for example, a casing of a device that uses the heating element 92 without requiring to be formed as a component independently of other members. For example, the heat sink 200, so that the heat sink 200 as a portion of the casing may be fixed via a portion other than the printed circuit board 91. That is, the method of attaching or installing the heat sink 200 is not to the case of placing the base portion 51 of the heat sink 200 on the printed circuit board 91.

According to the above configuration, the fan motor is placed on the heat sink. Then, the impeller of the fan motor is provided so as to be spaced apart from the heat radiation pins between the sleeve bearing unit of the fan motor and the heat radiation pins of the heat sink, and the heat radiation pins extend from the base portion of the heat sink toward the sleeve bearing unit of the fan motor in the direction along the rotation shaft of the fan motor. Thus, according to the above configuration, a top portion of the heat radiation pins is provided so as to be spaced apart from the impeller in a state of being opposed to the impeller of the fan motor.

Then, according to the above configuration, the blade support element of the fan motor and at least one heat radiation pin of the heat sink overlap each other as viewed in the axial direction of the rotation shaft of the fan motor. Therefore, even if the fan motor receives an impact from the outside and the impeller moves in a direction of being separated from the sleeve bearing unit together with the rotation shaft along the axial direction of the rotation shaft, since the blade support element of the fan motor returns to the original state immediately after coming into contact with the heat radiation pins of the heat sink, it is possible to prevent a separation of the impeller.

That is, it is possible to prevent the impeller from being separated from the sleeve bearing unit without using members other than the fan motor and the heat sink.

Thus, according to the above configuration, it is possible to provide a cooling device having a simplified structure using a fan motor which employs a sleeve bearing.

Another feature of the cooling device according to the aspect of this disclosure resides in that the heat radiation pins include a support pin having a length relatively longer than that of the other heat radiation pins, and the blade support element and the support pin overlap with each other as viewed in the axial direction of the rotation shaft.

According to the above configuration, when the impeller of the fan motor moves in the direction of being separated from the sleeve bearing unit together with the rotation shaft along the axial direction of the rotation shaft, the support pin of the heat sink comes into contact with the impeller blade support element before the other heat radiation pins of the heat sink. Thus, it is possible to prevent the impeller from being separated from the sleeve bearing unit.

Another feature of the cooling device according to the aspect of this disclosure resides in that an axis passing through a center of gravity of a cross section of the support pin and a rotational axis of the rotation shaft are coaxial.

According to the above configuration, when the impeller of the fan motor moves in the direction of being separated from the sleeve bearing unit together with the rotation shaft along the axial direction of the rotation shaft, a top portion of the support pin of the heat sink comes into contact with a portion of the rotation center (axis) of the blade support element of the fan motor. Therefore, it is possible to minimize a reduction in the rotational speed of the impeller when the support pin of the heat sink comes into contact with the blade support element of the fan motor. This is because, since the rotation center portion of the blade support element has a slower movement speed than that of a portion around the rotation center of the blade support element, a frictional resistance between the support pin and the blade support element when the support pin of the heat sink comes into contact with the portion of the rotation center (axis) of the blade support element of the fan motor becomes smaller than a frictional resistance between the support pin and the blade support element when the support pin of the heat sink comes into contact with the portion around the rotation center of the blade support element of the fan motor.

Another feature of the cooling device according to the aspect of this disclosure resides in that a tip end portion of the support pin forms a smooth curved surface that is convex from an outer peripheral portion of the support pin toward the blade support element.

According to the above configuration, when the support pin of the heat sink comes into contact with the blade support element of the fan motor, since the support pin and the blade support element are in point contact with each other, a frictional resistance between the support pin and the blade support element may be reduced.

Supplementally, according to the above configuration, as compared with a case where the tip end portion of the support pin is formed into a pointed sharp shape such as, for example, a conical shape so as to be in a point contact with the blade support element in order to reduce the frictional resistance, it is possible to reduce the wear of the tip end portion of the support pin without forming the tip end portion of the support pin into a pointed sharp shape while securing the point contact.

Another feature of the cooling device according to the aspect of this disclosure resides in that the curved surface is an SR spherical surface having a diameter equal to or larger than a diameter of a circle including the cross section of the support pin.

According to the above configuration, it is possible to further reduce the frictional resistance between the support pin and the blade support element when the support pin of the heat sink comes into contact with the blade support element of the fan motor. In addition, since the wear of the support pin may be reduced by reducing the frictional resistance, it is possible to enhance the robustness of the cooling device.

In addition, the configuration disclosed in the above embodiment (including other embodiments) may be applied in combination with the configuration disclosed in another embodiment unless a contradiction occurs. In addition, the embodiment disclosed in this specification is given by way of example, and the embodiment disclosed here is not limited thereto and may be appropriately modified within a scope not deviating from the object disclosed here.

This disclosure may be applied to a cooling device using a fan motor that employs a sleeve bearing.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A cooling device comprising:
a fan motor including a rotation shaft, an impeller supported by the rotation shaft to rotate integrally with the rotation shaft, and a sleeve bearing unit configured to pivotally support the rotation shaft; and
a heat sink including a plurality of heat radiation pins extending from a base portion,
wherein the fan motor is placed on the heat sink,
the impeller includes a blade support element supported by the rotation shaft and a fan blade extending from the blade support element in an outer peripheral direction of the rotation shaft,
the heat radiation pins extend from the base portion toward the sleeve bearing unit in a direction along the rotation shaft,
the impeller is spaced apart from the heat radiation pins between the sleeve bearing unit and the heat radiation pins, and
the blade support element and at least one of the heat radiation pins overlap with each other as viewed in an axial direction of the rotation shaft.

2. The cooling device according to claim 1,
wherein the heat radiation pins include a support pin having a length relatively longer than that of the other heat radiation pins, and
the blade support element and the support pin overlap with each other as viewed in the axial direction of the rotation shaft.

3. The cooling device according to claim 2,
wherein an axis passing through a center of gravity of a cross section of the support pin and a rotational axis of the rotation shaft are coaxial.

4. The cooling device according to claim 2,
wherein a tip end portion of the support pin forms a smooth curved surface that is convex from an outer peripheral portion of the support pin toward the blade support element.

5. The cooling device according to claim 4,
wherein the curved surface is an SR spherical surface having a diameter equal to or larger than a diameter of a circle including the cross section of the support pin.
